(19) United States
(12) Patent Application Publication
(10) Pub. No.: US 2008/0182105 A1
(43) Pub. Date: Jul. 31, 2008

(54) Production of Core/Shell Semiconductor Nanocrystals In Aqueous Solutions

(76) Inventors: Lian Hui Wang, Singapore (SG); Ji-En Wu, Singapore (SG); Lian Hui Zhang, Singapore (SG)

Correspondence Address: JACOBSON HOLMAN PLLC, 400 SEVENTH STREET N.W., SUITE 600, WASHINGTON, DC, 20004, US

(21) Appl. No.: 11/791,142

(22) PCT Filed: Nov. 9, 2005
(86) PCT No.: PCT/SG05/00382

§ 371 Date: May 21, 2007

Related U.S. Application Data
(60) Provisional application No. 60/629,478, filed on Nov. 19, 2004.

(51) Int. Cl. B32B 33/00; H01L 21/44

(52) U.S. Cl. 428/403; 438/678; 257/E21.476

(57) ABSTRACT

The present invention relates to a method of forming a core/shell nanocrystal of semiconductor material. Typically the core may comprise CdTe and the shell may be CdS. The shell is synthesised on the core in an aqueous solution. In the method, the previously synthesised cores are placed in the aqueous solution, reactants that form the shell and a thiol such as 3-mercaptopropionic acid (MPA) are added, and the mixture is refluxed until the completion of the shell at the desired thickness. The synthesis of the shell is aided by the provision of an interface zone between the shell and core so that lattice mismatch between the core and shell is reduced. The interface zone may be produced using a method that provides a gradient alloyed core with increased levels of sulphur, for example, at the surface relative to the centre of the core. Alternatively the interface zone may be a separate layer on a homogenous core.

The present invention relates to methods for forming core/shell semiconductor nanocrystals (NCs) or quantum dots (QDs); to NCs/QDs formed using the methods; and to the uses of such NCs/QDs.

Semiconductor nanocrystals (NCs; also termed quantum dots (QDs)) are portions of semiconductor material composed of a few hundreds to thousands of atoms. Nanocrystals/quantum dots have useful and interesting optical properties resulting from quantum confinement, which occurs in particles which are smaller than the Bohr excitation radius of the material they are composed. The range of properties of nanocrystals/quantum dots is reflected in a range of technical applications in the optoelectronic field, for example as discussed in WO 2004/039830 and WO 2004/054923. Luminescent semiconductor nanocrystals, for example, are currently being studied extensively due to their size-tunable emission properties.^{1,4} Varying the size of the nanocrystals allows the emission wavelength to be tuned whilst the absorption characteristics remain similar. A single light source can therefore be used for simultaneous excitation of particles of a range of sizes (and therefore emission wavelengths). Advances in synthesis of highly luminescent semiconductor nanocrystals promote their applications in different fields including bioimaging.⁵⁻⁸ There are two general strategies for NCs preparations, i.e., the organometallic synthesis based on the high-temperature thermolysis of the precursors ^{9,10} and the aqueous synthesis using various thiols as stabilizing agents.^{11,12} Although the high-temperature organometallic approaches can yield high-quality NCs with better crystallinity and higher luminescence quantum yields (QY), aqueous synthetic methods are simple, safe, inexpensive, reproducible, versatile, and easy to scale up. In addition, the aqueous synthetic approaches produce water-soluble NCs and are able to modify the surface properties of NCs simply by changing the stabilizing mercapto-compounds with appropriate free functional groups. These are important advantages for biological applications as they require water-soluble NCs and versatile functional groups for biomolecule coupling. Since 1996 when the aqueous synthesis of CdTe NCs was first reported,¹¹ significant progresses have been made in the preparation of thiol-capped CdTe NCs. However, lacking of the desired quality NCs with high luminescence quantum yields and photostability hinders many potential applications. The most common method to enhance the optical properties of luminescent NCs is to coat a higher band gap shell on the core particles using organic synthetic procedures; a thin-layer of inorganic shell such as ZnS or CdS on top of the core dramatically increases both the quantum yields and photostability due to elimination of the core surface traps by the shell. ^{13,14} Provision of a lower band gap shell is desirable in relation to other optoelectronic applications. However, it is not clear yet whether similar core/shell NCs can be prepared in aqueous solutions to improve the optical properties of NCs.

Recently, CdTe/ZnS and CdHgTe/ZnS were successfully synthesized by an aqueous-organic hybrid approach.¹⁵ In this method, the cores synthesized by an aqueous method were transferred from aqueous solution to organic solvents prior to coating the shell. The ideal method would be to complete the both core growth and shell coating processes in aqueous solution.

We report shell coating in aqueous solution. We provide, for example, a simple method to coat CdTe NCs with CdS in aqueous solution to yield photo stable CdTe/CdS core/shell NCs with a photolife at least ten times more than that of CdTe NCs. We consider that the CdS-rich pre-surface layer of CdTe cores, created by favorable reaction conditions, could play a crucial role in promoting the CdS shell growth by minimizing the lattice mismatch. The shell growth dramatically enhanced both luminescence quantum yield and photochemical stability of these NCs compared to the cores. The CdTe/CdS core/shell NCs prepared by this method showed the highest quantum yields (>50%) among all NCs synthesized in aqueous condition. This method can also be applied to the synthesis of other II-VI semiconductor core/shell NCs in aqueous solution. Importantly, by pre-modification of the surface layer of core particle, this method can be easily employed to synthesize, for example, photostable, highly luminescence core/shell NCs in aqueous solution. These findings will help to use greener chemistry approaches to synthesize NCs for various biotechnological applications.

A first aspect of the invention provides a method of providing a shell on a semiconductor nanocrystal core comprising the step of synthesising the shell on a previously-synthesised core in an aqueous medium.

The semiconductor nanocrystal can be an optoelectronic nanocrystal. The semiconductor nanocrystal can be a luminescent semiconductor nanocrystal.

The shell is considered to enhance considerably the optical properties of the nanocrystal. For example, the shell is considered to enhance luminescence quantum yield. The shell is also considered to enhance photochemical stability. For example, provision of a CdS shell on a gradient alloyed CdTeS nanocrystal dramatically enhanced both luminescence quantum yield and photochemical stability, as shown in the Examples.

Synthesis of the shell in an aqueous medium is considered to provide advantages over synthesis in organic media, for example in relation to cost, complexity, ease of scale-up and environmental acceptability. Further, synthesis of the shell in an aqueous medium is considered to produce water-soluble nanocrystals, with the possibility of modifying surface properties by providing different free functional groups (for example by using different stabilising mercapto-compounds with appropriate free functional groups). Water-solubility of the nanocrystals and free functional groups aids the coupling of biomolecules to the nanocrystals.

In an embodiment the previously-synthesised core is also synthesised in an aqueous medium. Advantages of synthesis in an aqueous medium are noted above.

We consider that aqueous synthesis of the shell is aided by reducing lattice mismatch between the surface of the core and the shell. This may be achieved by, for example, selection of suitable matched core and shell compositions; providing a gradient alloyed core, as discussed further below; or by providing a modified core on which has been provided a surface layer which has lower lattice mismatch with the shell than has the interior (centre) of the core. In the latter two cases the result is considered to be the provision of an interface zone between the shell and the interior of the core such that the predicted lattice mismatch between the shell and the surface on which it is provided is reduced relative to the predicted lattice mismatch between the shell and the interior (centre) of the core. This is considered to aid formation of the shell.

Accordingly, an embodiment of the invention provides a method of providing a shell on a semiconductor nanocrystal (for example a luminescent semiconductor nanocrystal) core comprising the step of synthesising the shell on a previously-synthesised core in an aqueous medium, wherein an interface zone is provided at the surface of the previously-synthesised core such that the lattice mismatch between the shell and the interface zone is predicted to be less than the lattice mismatch between the shell and the interior (centre) of the core.

The interface zone may be provided, for example, by synthesising the core using a method which provides a gradient alloyed core ie a core in which there is a continuous gradient of alloy composition between the centre and surface of the core. In this case, there may not be a distinct boundary between the interface zone and the central material of the core. Aqueous methods may be particularly useful in synthesising gradient alloyed cores.

The interface zone may alternatively be provided by synthesising a further layer on a core, for example a homogeneous core. For example, a core may be synthesised using non-aqueous techniques. An interface zone may then be synthesised on the core, for example using aqueous techniques, to generate a lower predicted lattice mismatch with the shell than for the interior of the core.

Acceptable levels of predicted lattice mismatch may be determined by testing combinations of core and shell with different predicted lattice mismatches. It is considered that the predicted lattice mismatch between the surface of the core (ie surface of the interface zone, if present) and the shell should be less than 20%, and preferably less than 10%, still more preferably less than 5%, 4%, 3% or 2%.

Lower lattice mismatch may be achieved by the interface zone having a composition intermediate between that of the shell and that of the core to be coated. Thus, for example, the interface zone may have a proportion of sulphur or Se that is intermediate between the shell and the core to be coated.

Accordingly, an embodiment of the invention provides a method of providing a shell on a semiconductor nanocrystal (for example a luminescent semiconductor nanocrystal) core comprising the step of synthesising the shell on a previously-synthesised core in an aqueous medium, wherein the predicted lattice mismatch between the shell and the surface of the core is less than 20%, preferably less than 10%, still more preferably less than 5%.

Lattice mismatch may be predicted using lattice constants of the core and shell. See, for example, Terheggen et al (2004) Interface Science 12, 259-266. Lattice mismatch can also be calculated by determining the lattice constants of core and shell, respectively, by using routine x-ray diffraction method.

The combination of core and shell may be determined by whether it is possible to achieve a low enough level of lattice mismatch to enable the shell to be synthesised and to provide desired properties, for example in relation to luminescence QY and photochemical stability.

The core and shell may comprise or consist of the same elements. The relative proportions of the elements typically differ in the core and shell. The core and shell may differ in relation to their lattice structure. The shell may have a higher band gap than the core for generation of strong luminescent nanocrystals/QDs, or a lower band gap than the core for production of nanocrystals/QDs suitable for other optoelectronic applications. Typically the core and shell may have different compositions.

In an embodiment the core comprises a Group II-VI semiconductor. A number of II-VI semiconductors have been synthesized in aqueous medium. The core may comprise CdS, CdSe, CdTe, ZnS or ZnSe. The shell may comprise CdS, ZnS, CdSe, ZnSe.

Alternatively, the core can comprise a group IIB-VI semiconductor. For example, the core can comprise Cd and Te. The core can comprise a cation (Zn, Cd, Hg), and a anion (S, Se, Te). Zn, Cd, Hg, S, Se, and Te. The core may comprise CdS, CdSe, CdTe, ZnS, ZnSe or mixtures thereof. The core can be a ternary or quaternary alloyed nanocrystal comprising the above elements. The core can comprise, for example, a gradient alloy of CdTeS. The shell may comprise CdS, ZnS, CdSe or ZnSe or mixtures thereof.

As an example, the previously-synthesised core can be synthesised using a method comprising the step of prolonged refluxing in an excess of thiols in basic medium. It is considered that the prolonged refluxing may lead to partial hydrolysis of the thiols and subsequent incorporation of the sulphur from the thiol molecules into the growing ) nanoparticles. This may lead to formation of a gradient alloyed core, for example a gradient of sulphur within the core, with increased sulphur levels at the surface relative to the centre of the core. The longer the reflux time, the greater the sulphur content may be. The reflux length controls the size and optical properties of the nanocrystal cores, but the reflex length required to achieve a given size of nanocrystal may vary greatly in different synthetic systems, for example with different stabilising agents or different pH, from several minutes to days. The reflux time is chosen to provide cores on which it is possible to coat a shell. If the reflux time is not long enough it is not possible to form a shell (as measured by elemental analysis or size analysis, for example using transmission electron microscopy (TEM)). It is considered that the prolonged refluxing generates a core surface that has a low lattice mismatch with the shell lattice.

Accordingly, the previously-synthesised core may be gradient alloyed such that the lattice mismatch between the surface of the core and the shell is predicted to be less than 20%, preferably less than 10% or 5%.

Similarly, for making a Selenium-containing core, for example a CdSe core, NaHSe can be formed by reaction of sodium borohydride and selenium powder, which is available from Aldrich. This reaction can be carried out in an analogous way to the reaction of sodium borohydride with tellurium powder. The NaHSe can then be reacted with CdCl₂ in the same way as NaHTe/CdCl₂ in the Examples. If MPA (3-mercaptopropionic acid) is used (as in the Examples), then a CdS-containing CdSe core would be obtained. We consider that under alkaline conditions, as used in the Examples, a small amount of S is released and reacts with Cd to deposit CdS. If the MPA is replaced in this reaction with the corresponding selenopropionic acid, then a CdSe core is obtained. However, selenopropionic acid is very toxic, and has poor stability in water, so it is not recommended for use as a stabilising agent.

As an alternative to a sulphur-containing shell, a Se-containing shell may be formed. It is considered that an Se-containing shell can match the lattice of the core.

To make a CdSe shell, methods similar to those used in the Examples may be used. The Na₂S can be replaced with Na₂Se (sodium selenide). It may also be desirable to replace the MPA used in the shell-forming step with the corresponding selenopropionic acid, though this is not essential: because CdSe can be formed much faster than CdS, there will be only a little sulphur content using MPA as a stabilising agent). If MPA is used there will be minor sulphur content in the shell. The selenoproprionic acid can be used if no S content in the CdSe shell is required. However, replacement of MPA by selenoproprionic acid is not considered to be essential.

A further aspect of the invention provides the use of 3-mercaptopropionic acid (MPA) in the synthesis of a CdTe(S) nanocrystal.

In a further alternative the core can comprise a group III-V semiconductor, for example GaAs, GaP, InGaAs, InP, IriAs or mixtures thereof.

The core can comprise an alloy as set out in WO 2004/054923. Thus, the core can comprise a homogeneous ternary alloy having the composition M1₁₋ₓM2ₓA, wherein
a) M1 and M2 are independently selected from an element of subgroup IIb, subgroup VIIa, subgroup VIIIa, subgroup Ib or main group II of the periodic system of the elements (PSE), when A represents an element of the main group VI of the PSE, or
b) M1 and M2 are both selected from an element of the main group (III) of the PSE, when A represents an element of the main group (V) of the PSE, obtainable by a process comprising
i) forming a binary nanocrystal M1A by heating a reaction mixture containing the element M1 in a form suitable for the generation of a nanocrystal to a suitable temperature T1, adding at this temperature the element A in a form suitable for the generation of a nanocrystal, heating the reaction mixture for a sufficient period of time at a temperature suitable for forming said binary nancrystal M1A and then allowing the reaction mixture to cool, and
ii) reheating the reaction mixture, without precipitating or isolating the formed binary nanocrystal M1A, to a suitable temperature T2, adding to the reaction mixture at this temperature a sufficient quantity of the element M2 in a form suitable for the generation of a nanocrystal, then heating the reaction mixture for a sufficient period of time at a temperature suitable for forming said ternary nanocrystal M1₁₋ₓM2ₓA and then allowing the reaction mixture to cool to room temperature, and isolating the ternary nanocrystal M1₁₋ₓM2ₓA.

Alternatively, the core can comprise a homogeneous ternary alloy (as also described in WO 2004/054923) having the composition M1_{1-31 x}M2ₓA_{y}B₁₋, wherein
a) M1 and M2 are independently selected from an element of the subgroup IIb, subgroup VIIa, subgroup VIIIa, subgroup Ib or main group II of the periodic system of the elements (PSE), when AS and B both represent an element of the main group VI of the PSE, or
b) M1 and M2 are independently selected from an element of the main group (III) of the PSE, when A and B both represent an element of the main group (V) of the PSE, obtainable by a process comprising
   a. Providing a reaction mixture containing the elements M1, M2, A and B each in a form suitable for the generation of a nanocrystal,
   b. Heating the reaction mixture for a sufficient period of time at a temperature suitable for forming said quaternary nanocrystal M1₁₋ₓM2ₓA_{y}B_{1-y} and then allowing the reaction mixture to cool, and
   c. Isolating the quaternary nanocrystal M1₁₋ₓM2ₓA_{y}B_{1-y}.

Preferences in relation to these core compositions are as set out in WO 2004/054923.

When the core comprises a group II-VI semiconductor, the shell may comprise CdS. In this case, the method may comprise the step of combining in an aqueous medium the previously synthesised core, a Cd salt, a sulphide and a thiol. The order of addition is not critical. The reaction mixture may then be refluxed until the desired shell thickness is achieved. This may be measured by TEM or by assessing optical properties, for example assessment of quantum yield (QY), photoluminescence stability or emission wavelength shift. Examples of such assessments and suitable measurement techniques are indicated in the Examples.

Alternatively, the shell may comprise CdSe, ZnS or ZnSe, in which case the Cd salt is replaced with a Zn salt and the sulphide is replaced with equivalent Se compound(s). A thiol is necessary to provide a functional group for coupling with biomolecules (if required). The thiol is considered to be connected to the shell (on the outside of the shell) but is not considered to form the integral part of the shell.

The thiol can be 3-mercaptopropionic acid (MPA). In general water-soluble thiol molecules can be used as a stabilising agent. Suitable examples are indicated in Gaponik et al (2002) J Phys Chem B, 106, 7177-7185. Different thiols with appropriate free functional groups can be used to aid coupling of biomolecules. For example, QD-COOH/H₂N-protein, QD-NH₂/HOOC-protein, QD-NH₂-O₄PH-DNA, QD-COOH/ H₂N-[small molecule], QD-NH₂/HOOC-[small molecule].

A further aspect of the invention provides a core/shell nanocrystal (for example luminescent semiconductor nanocrystal) obtainable by the method of the invention. The core/shell nanocrystal (for example luminescent semiconductor nanocrystal) obtainable by the method of the invention may comprise a gradient alloyed core and a shell; or may comprise a homogeneous core, an interface zone and a shell. The core/shell nanocrystals obtainable by the method of the invention may have lower crystallinity than core/shell nanocrystals obtained using non-aqueous techniques, but the quality of nanocrystals/QDs (for example luminescent semiconductor nanocrystals) obtained by the aqueous method is considered good enough for most applications, if not all.

The method or core/shell nanocrystals (typically luminescent semiconductor nanocrystals) of the invention may be used in many biolabelling and bioimaging applications, as will be apparent to those skilled in the art. The aqueous shell synthesis aids coupling of biomolecules to the nanocrystals, as noted above. Examples of biolabelling and bioimaging applications are described in, for example, U.S. Pat. No. 6,207,392 and WO 2004/039830 (for example in paragraphs 0018 to 0020; 0070 to 0082). Further examples are described in WO 2004/054923.

Thus, in an embodiment, a method of the invention further comprises the step of coupling to the core/shell nanocrystal a molecule having binding affinity for a given analyte. The invention also provides a core/shell nanocrystal obtainable by the method of the invention wherein a molecule having binding affinity for a given analyte is coupled to the core/shell nanocrystal. By conjugation to a molecule having binding affinity for a given analyte, a marker compound or probe is formed in which the core/shell nanocrystal of the invention serves as a label or tag which emits radiation, preferably in the visible or near infrared range of the electromagnetic spectrum (as for an unconjugated core/shell nanocrystal of the invention), that can be used for the detection of a given analyte.

Details of suitable analytes and specific binding partners will be apparent to those skilled in the art and are described, for example in WO 2004/054923, for example in paragraphs 0065 to 0068 (incorporated herein by reference).

Examples of linking agents which can be used in joining a nanocrystal of the invention to the molecule having binding activity for the analyte are also described in WO 2004/054923, for example in paragraph 069, which also discusses how linking agents may be used. For example, as noted in WO 2004/05923, an example of a suitable linking agent is the bifunctional linking agent ethyl-3-dimethylaminocarbodiimide (EDC). Coupling using EDC can be performed at room temperature.

The nanocrystals of the present invention may also be used in compositions or devices as described in paragraphs 0070 and 0071 of WO 2004/054923. Accordingly, the invention also provides a composition (for example a plastic or latex bead) containing at least one core/shell nanocrystal of the invention. The invention also provides a detection kit comprising a core/shell nanocrystal or a composition of the invention. The invention provides a kit of parts comprising 1) a core/shell nanocrystal or a composition of the invention and either or both of 2) a linking reagent (as discussed above, for example EDC) and 3) a molecule having binding affinity for a given analyte (as discussed above; examples include an antibody or antibody fragment or a nucleic acid molecule). The kit may, for example, comprise more than one type of molecule having binding affinity for a given analyte, for example several types of molecule each having binding affinity for a different given analyte. The kit may also comprise more than one type of core/shell nanocrystal or composition of the invention.

The invention is now described in more detail by reference to the following, non-limiting, Figures and Examples.

All documents referred to herein are hereby incorporated by reference.

Figure Legends

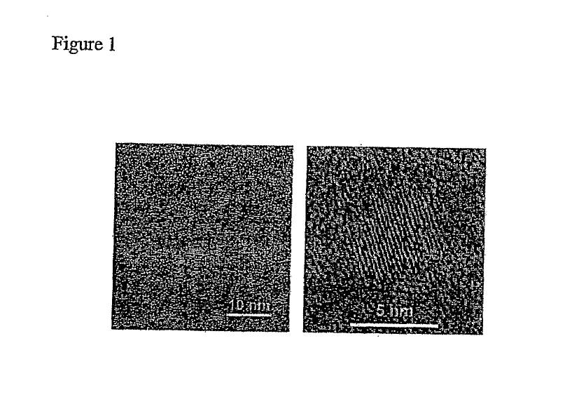

FIG. 1. TEM overview of CdTe/CdS NCs (a) and HRTEM image (b) of a single CdTe/CdS nanocrystal.

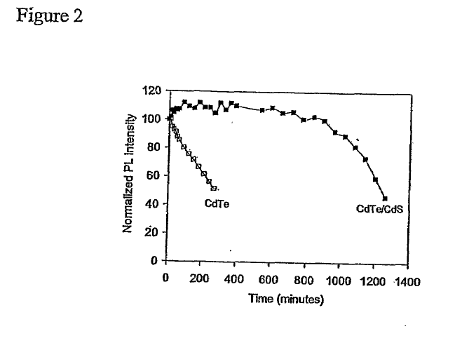

FIG. 2. Photochemical stability of CdTe and CdTe/CdS NCs under UV radiation in air.

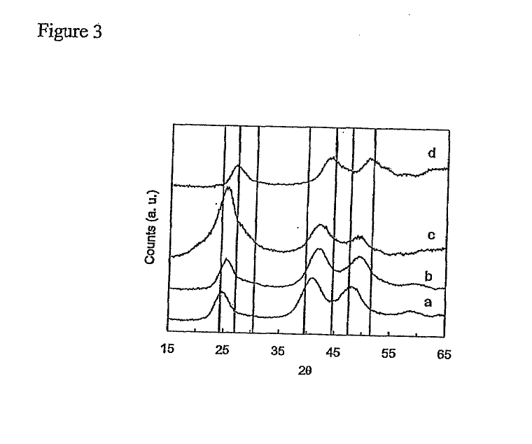

FIG. 3. Temporal evolution of powder X-ray diffraction patterns of CdTe and CdTe/CdS NCs. (a) CdTe 24-h refluxed; (b) CdTe/CdS 24-h refluxed; (c) CdTe 96-h refluxed; (d) CdTe/CdS 96-h refluxed. The line spectra indicate the reflections of bulk cubic CdS (top) and cubic CdTe (bottom).

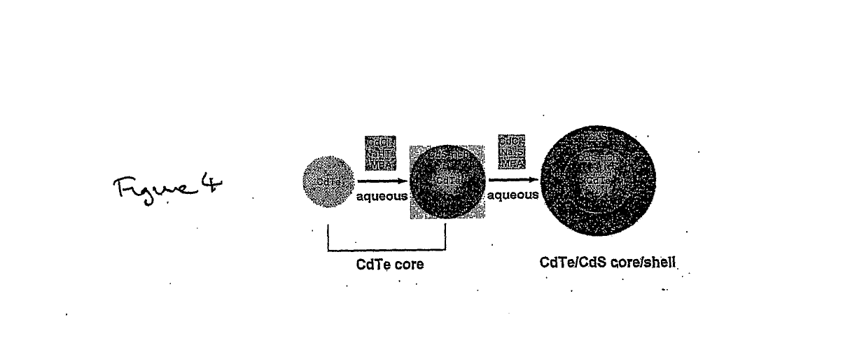

FIG. 4. Schematic diagram of a gradient alloyed core and shell, exemplified by a CdTeS core and CdS shell.

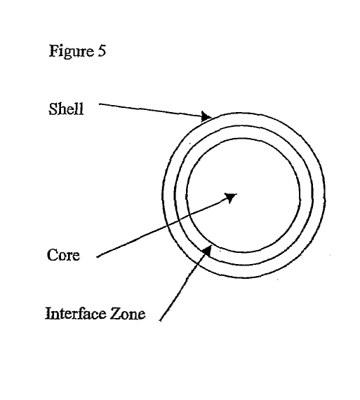

FIG. 5. Schematic diagram of a homogeneous core, interface zone and shell.

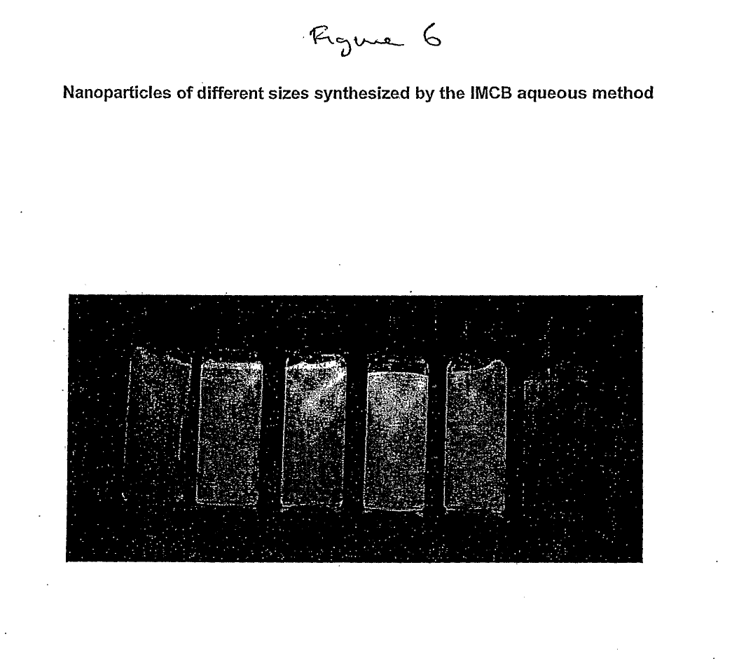

FIG. 6. Nanoparticles of different sizes synthesized by aqueous methods.

### EXAMPLE 1

### Aqueous Synthesis of CdTe/CdS Core/shell Nanocrystals with High Luminescence and Photochemical Stability

We report shell coating in aqueous solution. We provide, for example, a simple method to coat CdTe NCs with CdS in aqueous solution to yield photo stable CdTe/CdS core/shell NCs with a photolife at least ten times more than that of CdTe NCs. The CdTe core was synthesized in water by injecting freshly prepared NaHTe solution into N₂-saturated CdCl₂ solution at pH 8.4 in the presence of 3-mercaptopropionic acid (MPA) as a stabilizing agent by modification of the previously reported approach. ¹¹ CdTe cores with different sizes were obtained by controlling the refluxed time. In a typical experiment, we precipitated the CdTe cores, which are approximately 3.4 nm in diameter, with 2-propanol after refluxed for 12 h. The cores were then washed, and then redissolved in water for coating a shell. For shell synthesis, a solution consisting of CdCl₂, Na₂S and MPA was injected into the aqueous solution containing CdTe cores; the reaction mixture was then refluxed until the completion of the shell at the desired shell thickness.

The TEM images of CdTe/CdS core/shell NCs (FIG. 1a) show that these NCs have narrow size distributions with a relative standard deviation of 15%. When the shell growth reaction was allowed for 24 hours (h), the particle size increased from 3.4 nm to 5.0 nm in diameter, suggesting a 0.8-nm CdS shell coated the original core. The HRTEM images indicate that CdTe/CdS NCs have well-resolved lattice fringes and remain fully crystalline after shell growth (FIG. 1b). The quantum yield was increased from 30% (core) to over 50% (with shell) in nearly identical sizes of 5 nm. Accompanied with the increase of QY, the emission of CdTe/CdS was red shifted by 40 nm from 550 nm to 590 nm upon shell growth, which is 17-nm less than that of the same sized CdTe NCs (607 nm). However, the full width half-maximum (fwhm) of the photoluminescence peak of CdTe/CdS NCs was almost identical to that of the cores, indicating that the shell growth reaction did not cause significant variation in NCs size distribution.

It is impressive to note that the photoluminescence stability of CdTe/CdS NCs (FIG. 2) was dramatically improved from no more than 1 h (normalized PL intensity≧90%) for cores to over 10 h for core/shell NCs, measured by the procedure described previously.¹⁶ This phenomenon suggests that a complete outer CdS shell was probably formed around the CdTe core, which inhibited the photooxidation of the surface unsaturated Te atoms of the CdTe core. The unsaturated Te atoms were identified as hole traps by optically detected magnetic resonance ¹⁷ and are known to be highly susceptible to oxidation. ¹⁸ Evidence for shell growth was further provided by elemental analysis using inductively coupled plasma atomic absorption. The molar ratio of Cd:Te:S of CdTe and CdTe/CdS NCs was found to be ˜3:1:2 and ˜5:1:4 at 24-h refluxed, then changed to be ˜4:1:3 and ˜11:1:10, respectively, after a prolonged refluxing of 96 h. The Cd and S contents of CdTe/CdS NCs are much higher than that ) of CdTe cores in the same refluxed time frame, suggesting a relatively thick CdS shell grown over the CdTe core. XRD patterns (FIG. 3) show the certain differences between CdTe and CdTe/CdS NCs. Although the positions of the XRD reflexes of both CdTe and CdTe/CdS NCs are in between the values of the cubic CdTe and the cubic CdS phase, all peaks of CdTe/CdS NCs are closer to the pattern of cubic CdS than that of CdTe NCs (FIG. 3, a & b); the tendency of CdTe/CdS NCs to shift from those characteristics of CdTe to those of CdS is more obvious after a prolonged refluxing of 96 h (FIG. 3, c & d).

The CdTe NCs prepared using our modified method were not pure CdTe crystalline, but most likely mixed CdTe(S) nanocrystals based on the XRD pattern analysis (FIG. 3, a & c). According to the literature¹⁹, prolonged refluxing of the aqueous colloidal solutions of CdTe nanocrystals in the presence of an excess of thiols in basic media led to partial hydrolysis of the thiols and subsequent incorporation of the sulfur from the thiol molecules into the growing nanoparticles. In this study, the core preparation was conducted in the presence of MPA at pH 8.2˜8.4 for at least 12 h. Therefore, it is rational to speculate that the CdTe NCs synthesized in this study is gradient alloyed CdTeS NCs, with a Te-rich core and a gradient increased sulfur distribution from the core to the surface. This is consistent with the elemental analysis. described above that the synthesized CdTe cores contained a high ratio of S element. It is important to note that prolonged refluxing time resulted in further enhanced content of S and Cd (over Te) in the CdTe NCs, suggesting the formation of a relative CdS-rich particle surface.

Although many II-IV semiconductor core/shell NCs have been prepared in high-temperature nonaqueous approaches, none was synthesized by aqueous methods. The major reason is probably that the temperature applied in aqueous synthesis was too low to promote the epitaxial growth of the shell on the core due to the lattice mismatch between the core and shell materials. Consistent with this notion, we failed in our initial attempts to coat a CdS shell on nearly pure CdTe core (prepared in a short refluxing time of 2 h) in the aqueous condition presumably because of the large lattice mismatch of roughly 10%. However, as mentioned above, a complete CdS shell can be formed on the gradient alloyed CdTeS NCs with CdS-rich pre-surface under an aqueous condition. Based on these results, we propose that the CdS-rich surface of these NCs facilitates the epitaxial growth of the outer CdS shell since the lattice mismatch is close to zero.

Materials and Methods:

Chemicals. Tellurium powder (200 mesh, 99.8%), cadmium chloride (99%), sodium borohydride (98%), 3-mercaptopropionic acid (MPA) (99%), 2-propanol, and Na₂S were purchased from Aldrich. All chemicals were used without further purification.

Measurements. Elemental analyses were measured on a Thermal Jarrell Ash Duo Iris Inductively Coupled Plasma-Optical Emission Spectrometer. XRD patterns were recorded on a Philips Analytical X'Pert X-ray diffractometer. TEM images were taken by a Philips FE CM300 Transmission Electron Microscope.

Preparation of NaHTe. Sodium borohydride (92 mg) was transferred to a small flask; then 2.4 mL of ultrapure water and 127.6 mg of tellurium powder were added subsequently. The reaction was carried out at room temperature. After approximately 5 h, the black tellurium powder disappeared and sodium tetraborate white precipitation appeared on the bottom of the flask. The resulting NaHTe in clear supernatant was separated and used in the preparation of CdTe NCs.

Synthesis of CdTe/CdS Core/Shell NCs.

CdTe core synthesis: A series of aqueous colloidal solution of CdTe NCs were synthesized by adding freshly prepared NaHTe solutions to N₂-saturated CdCl₂ solutions of pH 8.4 in the presence of MPA as a stabilizing agent. Briefly, a solution of 1.25 mM CdCl₂ and 3.0 mM MPA in 100 ml of ultrapure water was adjusted to pH 8.4 with 0.5 M NaOH. The solution was added into a three-necked flask and degassed with N₂ for 30 min at room temperature. After the solution was heated to 100° C. under N₂, 125 μl of freshly prepared oxygen-free NaHTe solution was injected rapidly under vigorous stirring. The resulting mixture was then refluxed to promote the core growth to the desired size.

CdS shell synthesis: The colloidal CdTe solution was concentrated by 4 times, then precipitated and washed by 2-propanol twice. The CdTe cores were dispersed in the solution of 1.25 mM CdCl₂, 1.0 mM Na₂S, and 6.0 mM MPA in pH 8.4. The mixture was degassed by N₂ for 30 min, was then heated to refluxing until the completion of the shell at the desired shell thickness.

Characterization of CdTe and CdTe/CdS Core/shell NCs. For the XRD studies, NCs were precipitated by these procedures: the solution was concentrated 4 times under vacuum; 2-propanol was dropped until the solution just became cloudy; the nanoparticles were collected by centrifugation (10,000 rpm for 10 min), washed twice by 2-propanol and dried under vacuum for overnight. For elemental analysis, the above NCs powder was digested by HCl-HNO₃ solution. A colorless solution was obtained. The Cd, Te, S content of the clear solution was detected with inductively coupled plasma (ICP) atomic absorption. For Size distribution analysis, the solution of nanocrystals was diluted by water. The solution was analyzed by TEM and diameters of the nanocrystals were measured by computer. In total, 174 nanocrystals were counted.

References

(1) Henglein, A. Chem. Rev. 1989, 89, 1861-1873.

(2) Alivisatos, A. P. J. Phys. Chem. 1996, 100, 13226-13239.

(3) Heath, J. R., Ed. Acc. Chem. Res. 1999, 32, 389-414.

(4) Murray, C. B.; Kagan, C. R.; Bawendi, M. G. Annu. Rev. Mater. Sci 2000, 30, 545-610.

(5) Bruchez, M., Jr.; Moronne, M.; Gin, P.; Weiss, S.; Alivisatos, A. P. Science 1998, 281, 2013-2015.

(6) Chan, W. C. W.; Nie, S. M. Science 1998, 281, 2016-2018.

(7) Dahan, M.; Levi, S.; Luccardini, C.; Rostaing, P.; Riveau, B.; Triller, A. Science 2003, 302, 442-445.

(8) Medintz, I. L.; Clapp, A. R.; Mattoussi, H.; Goldman, E. R.; Fisher, B.; Mauro, J. M. Nature Materials 2003, 2, 630-638

(9) Murray, C. B.; Norris, D. J.; Bawendi, M. G. J. Am. Chem. Soc. 1993, 115, 8706-8715.

(10) Peng, Z. A.; Peng, X. G. J. Am. Chem. Soc. 2001, 123, 183-184.

(11) Rogach, A. L.; Katsikas, L.; Kornowski, A.; Su, D. S.; Eychmüller, A.; Weller, H. Ber. Bunsen-Ges. Phys. Chem. 1996,100, 1772-1778

(12) Rogach, A. L.; Kornowski, A.; Gao, M. Y.; Eychmuller, A.; Weller, H. J. Phys. Chem. B 1999 103, 3065-3069.

(13) Peng, X. G; Schlamp, M. C.; Kadavanich, A. V.; Alivisatos, A. P. J. Am. Chem. Soc. 1997, 119, 7019-7029.

(14) Dabbousi, B. O.; Rodriguez-Viejo, J.; Mikulec, F. V.; Heine, J. R.; Mattoussi, H.; Ober, R.; Jensen, K. F.; Bawendi, M. G. J. Phys. Chem. B 1997, 101, 9463-9475.

(15) Tsay, J. M.; Pflughoefft, M.; Bentolila, L. A.; Weiss, S. J. Am. Chem. Soc. 2004, 126, 1926-1927.

(16) Aldana, J.; Wang, Y. A.; Peng, X. G J. Am. Chem. Soc. 2001, 123, 8844-8850.

(17) Glozman, A.; Lifshitz, E.; Hoppe, K.; Rogach, A. L.; Weller, H.; Echymüller, A. Isr. J. Chem. 2001, 41, 39-44.

(18) Resch, U.; Weller, H.; Henglein, A. Langmuir 1989, 5, 1015-1020.

(19) Rogach, A. L. Mat. Sci. Eng. B. 2000, 69-70, 435-440.

1. A method of providing a shell on a semiconductor nanocrystal core comprising the step of synthesising the shell on a previously-synthesised core in an aqueous medium, wherein aqueous synthesis of the shell is aided by reducing lattice mismatch between the surface of the core and the shell, and an interface zone is provided at the surface of the previously-synthesised core such that the lattice mismatch between the shell and the interface zone is predicted to be less than the lattice mismatch between the shell and the interior (centre) of the core.

2. The method of claim 1 wherein the interface zone is provided by synthesising the core using a method which provides a gradient alloyed core.

3. The method of claim 1 wherein the interface zone is provided by synthesising a further layer on a core.

4. The method of claim 3 wherein the further layer comprises a gradient alloy.

5. The method of claim 1 wherein the previously-synthesised core is synthesised in an aqueous medium.

6. The method of claim 1 wherein the predicted lattice mismatch between the shell and the surface of the core is less than 20%, 10%, or 5%.

7. The method of claim 3 wherein the previously-synthesised core is synthesised using a method comprising the step of prolonged refluxing in an excess of thiols in basic medium.

8. The method of claim 1 wherein the core comprises a Group IIB-VI semiconductor.

9. The method of claim 8 wherein the core comprises Cd and Te.

10. The method of claim 9 wherein the core comprises CdTeS.

11. The method of claim 8 wherein the shell comprises CdS

12. The method of claim 1 wherein the core comprises a group III-V semiconductor.

13. The method of claim 1 wherein the core comprises a homogeneous ternary alloy having the composition M1₁₋ₓM2ₓA, wherein
a) M1 and M2 are independently selected from an element of subgroup IIb, subgroup VIIa, subgroup VIIIa, subgroup Ib or main group II of the periodic system of the elements (PSE), when A represents an element of the main group VI of the PSE, or
b) M1 and M2 are both selected from an element of the main group (III) of the PSE, when A represents an element of the main group (V) of the PSE,
obtainable by a process comprising
i) forming a binary nanocrystal M1A by heating a reaction mixture containing the element M1 in a form suitable for the generation of a nanocrystal to a suitable temperature T1, adding at this temperature the element A in a form suitable for the generation of a nanocrystal, heating the reaction mixture for a sufficient period of time at a temperature suitable for forming said binary nanocrystal M1A and then allowing the reaction mixture to cool, and
ii) reheating the reaction mixture, without precipitating or isolating the formed binary nanocrystal M1A, to a suitable temperature T2, adding to the reaction mixture at this temperature a sufficient quantity of the element M2 in a form suitable for the generation of a nanocrystal, then heating the reaction mixture for a sufficient period of time at a temperature suitable for forming said ternary nanocrystal M1₁₋ₓM2ₓA and then allowing the reaction mixture to cool to room temperature, and isolating the ternary nanocrystal M1₁₋ₓM2ₓA.

14. The method of claim 1 wherein the core comprises a homogeneous quaternary alloy having the composition M1₁₋ₓM2ₓA_{y}B₁₋, wherein
a) M1 and M2 are independently selected from an element of the subgroup IIb, subgroup VIIa, subgroup VIIIa, subgroup Ib or main group II of the periodic system of the elements (PSE), when AS and B both represent an element of the main group VI of the PSE, or
b) M1 and M2 are independently selected from an element of the main group (III) of the PSE, when A and B both represent an element of the main group (V) of the PSE, obtainable by a process comprising
a. Providing a reaction mixture containing the elements M1, M2, A and B each in a form suitable for the generation of a nanocrystal,
b. Heating the reaction mixture for a sufficient period of time at a temperature suitable for forming said quaternary nanocrystal M1₁₋ₓM2ₓA_{y}B_{1-y} and then allowing the reaction mixture to cool, and
c. Isolating the quaternary nanocrystal M1₁₋ₓM2ₓA_{y}B_{1-y}.

15. The method of claim 7 wherein the method comprises the step of introducing into an aqueous medium containing the previously synthesised core a Cd salt, a sulphide and a thiol.

16. The method of claim 12 wherein the thiol is 3-mercaptopropionic acid (MPA).

17. The method of claim 1 further comprising the step of coupling to the core/shell nanocrystal a molecule having binding affinity for a given analyte.

18. A nanocrystal obtainable by the method of claim 1 comprising a core and a shell.

19. A nanocrystal of claim 18 further comprising a gradient alloy interface zone between the core and the shell.

20. A nanocrystal according to claim 19 wherein a molecule having binding affinity for a given analyte is coupled to the core/shell nanocrystal.

21. A composition containing at least one core/shell nanocrystal according to claim 18.

22. A detection kit comprising a core/shell nanocrystal according to claim 18.

23. A kit of parts comprising 1) a core/shell nanocrystal according to claim 18 and either or both of 2) a linking reagent and 3) a molecule having binding affinity for a given analyte.
